(19) United States
(12) Patent Application Publication
(10) Pub. No.: US 2006/0244008 A1
(43) Pub. Date: Nov. 2, 2006

(54) Light tunnel structure

(75) Inventors: Jen-Chih Wang, Taoyuan Hsien (TW); Ching-Hsiang Yu, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/230,471

(22) Filed: Sep. 21, 2005

(30) Foreign Application Priority Data
Apr. 28, 2005 (TW) 94113696

(51) Int. Cl. H01L 31/00

(52) U.S. Cl. 257/186

(57) ABSTRACT

The light tunnel structure includes a plurality of reflectors joined together to form a light tunnel for allowing a light beam to pass and reflect therethrough. The plurality of reflectors have edges at an end of the light tunnel structure, wherein not all of the edges at the end are positioned at the same plane.

### BACKGROUND

The invention relates to a light tunnel structure, and in particular, to a light tunnel structure for a projection system wherein the light axis of the light source and the central axis of the light tunnel structure are not parallel.

A light tunnel structure is generally used in a projection system to uniformize a light beam passing therethrough.

Referring to FIG. 1, a conventional light tunnel structure 100 includes four glass plates 101 laterally joined together to form a light tunnel 102 for a light beam to pass therethrough. The inner surfaces of the glass plates are coated with an optical film for reflecting the light beam. The four glass plates 101 have the same length so that the edges thereof at either end of the light tunnel structure 100 are positioned at a same plane.

The light beam emitted from a light source (not shown) cannot fully enter the light tunnel structure 100, if the light axis of the light source and the central axis of the light tunnel structure 100 are not parallel. Thus, the luminous intensity of the light beam output from the light tunnel structure 100 is poor in use.

In the conventional light tunnel structure, the light axis of the light source is necessarily in alignment with the central axis of the light tunnel structure 100 to avoid any light loss.

To solve the described problem, the invention provides a light tunnel structure effectively receiving and uniformizing a light beam even when the light axis of the light source and the central axis of the light tunnel structure are not parallel.

A light tunnel structure in accordance with an exemplary embodiment of the invention includes a plurality of reflectors joined together to form a light tunnel for a light beam to pass and reflect therethrough. The inner surfaces of the reflectors are coated with films for reflecting the light beam.

One or more reflectors protrudes at an end of the light tunnel structure. When the light axis of a light source and the central axis of the light tunnel structure are not parallel, the light beam of a projection system is still led into the light tunnel structure by the protruding reflector.

The profile of the reflectors may be trapezoid, rectangular, regularly polygonal or irregularly polygonal. Furthermore, the reflectors are made of, for example, glass.

The projection system, in which the light axis and the central axis are parallel or not, is suitable for the light tunnel structure of the invention.

The light tunnel structure of the invention is capable of maintaining the luminous intensity of a light beam without requiring the precise alignment of the light axis thereof.

### BRIEF DESCRIPTION OF THE DRAWINGS

The invention can be more fully understood by reading the subsequent detailed description and examples with references made to the accompanying drawings, wherein:

FIG. 1 depicts a light tunnel structure described in the background;

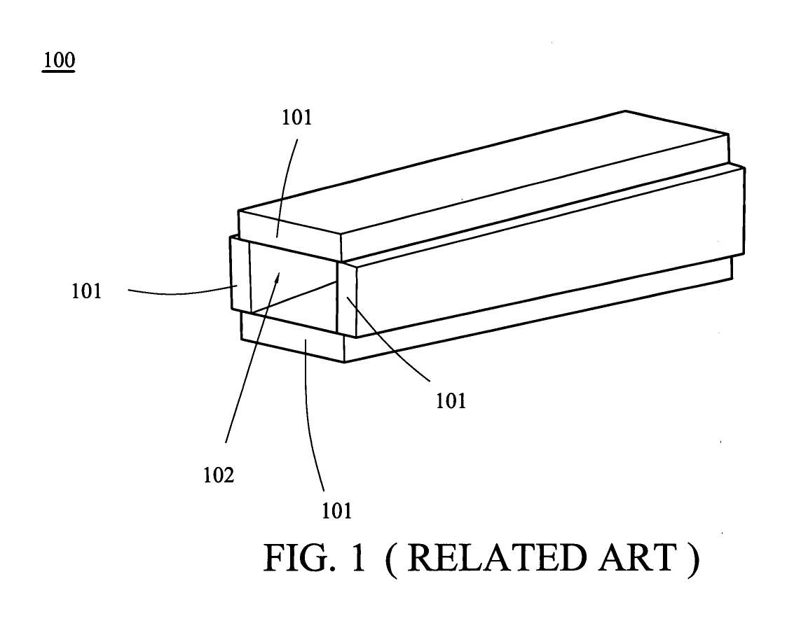

FIG. 2 depicts a light tunnel structure in accordance with an embodiment of the invention;

FIG. 3 depicts a light tunnel structure in accordance with another embodiment of the invention;

FIG. 4 depicts a light tunnel structure in accordance with another embodiment of the invention;

FIG. 5 depicts a light tunnel structure in accordance with another embodiment of the invention;

FIG. 6 depicts a light tunnel structure in accordance with another embodiment of the invention.

### DETAILED DESCRIPTION

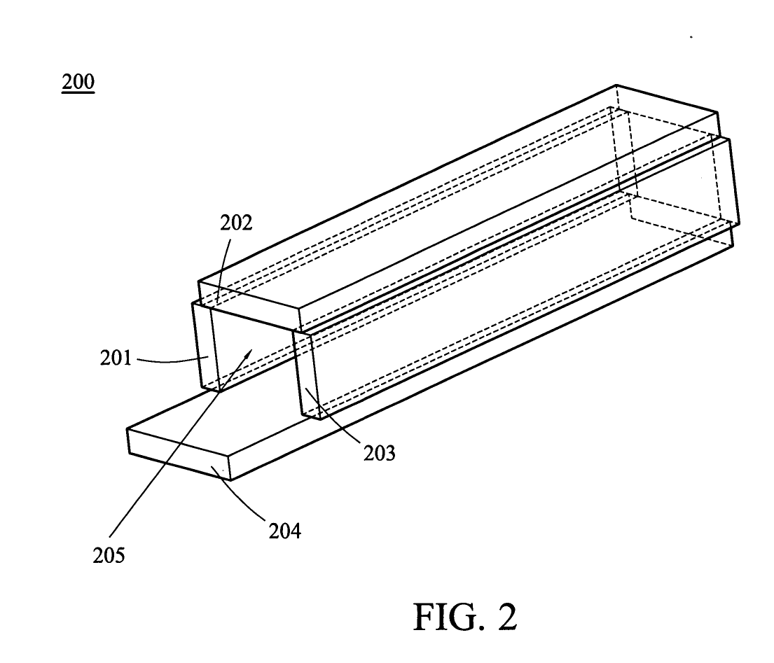

FIG. 2 depicts a light tunnel structure in accordance with an embodiment of the invention, wherein the light tunnel structure 200 includes a first reflector 201, a second reflector 202, a third reflector 203 and a fourth reflector 204. The reflectors 201, 202, 203 and 204 are made of, for example, glass, with a reflective film coated on the inner surfaces thereof. Furthermore, the profile of the reflectors 201, 202, 203 and 204 may be trapezoid, rectangular or polygonal.

In this embodiment, the fourth reflector 204 is longer than the first, second and third reflectors 201, 202 and 203. The reflectors 201, 202, 203 and 204 are laterally joined together to form a light tunnel 205, in which a light beam (not shown) passing therethrough is reflected. At an end of the light tunnel structure 200, the first, second and third reflectors 201, 202 and 203 have coplanar edges while the fourth reflector 204 protrudes. At the other end, the edges of the first, second, third and fourth reflectors 201, 202, 203 and 204 are positioned at the same plane, facilitating the positioning of the reflectors 201, 202, 203 and 204.

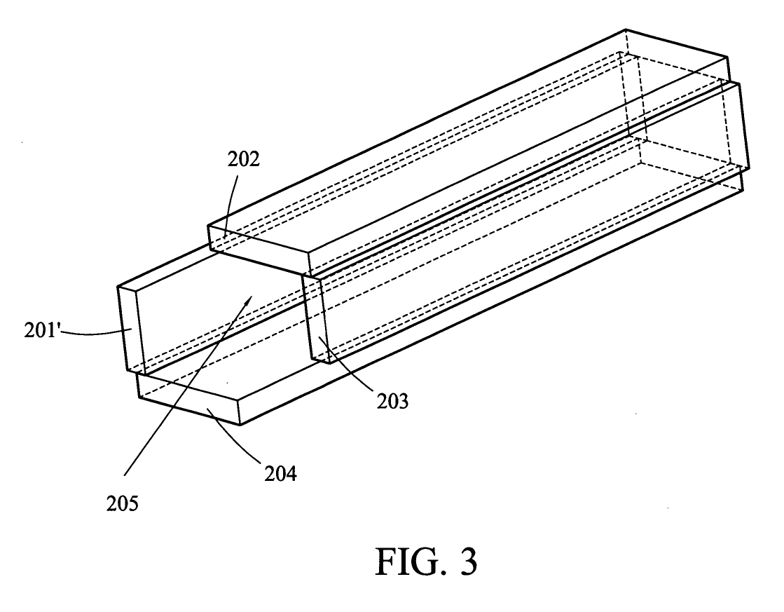

FIG. 3 depicts a light tunnel structure in accordance with another embodiment of the invention, wherein previously referenced elements share the same reference numerals. In this embodiment, the first reflector 201′ is as long as the fourth reflector 204 and longer than the second and third reflectors 202 and 203. At an end of the light tunnel structure, the second and third reflectors 202, 203 have coplanar edges while the first and fourth reflectors 201′ and 204 protrude and also have coplanar edges. At the other end, edges of the first, second, third and fourth reflectors 201′, 202, 203 and 204 are positioned at the same plane, thereby determining the positions of the reflectors 201′, 202, 203 and 204.

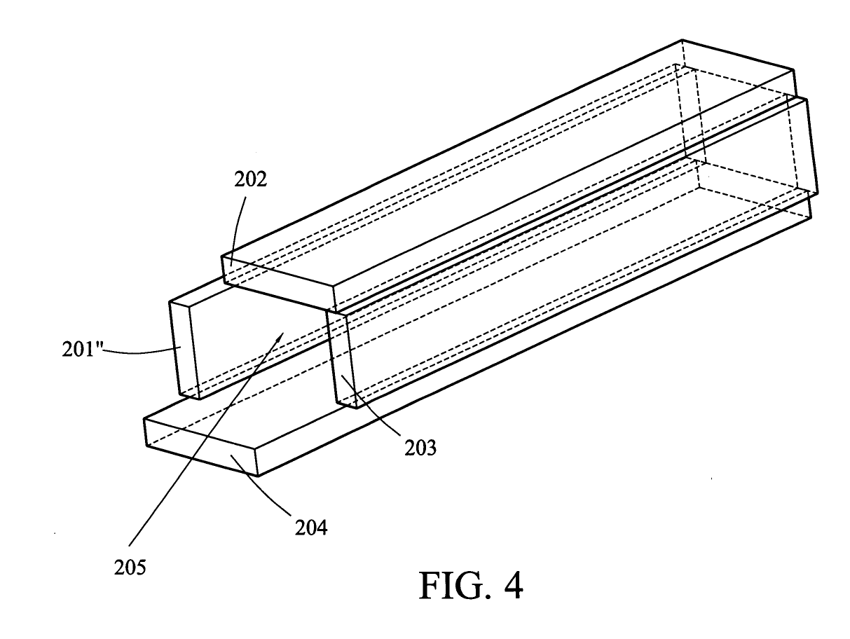

FIG. 4 depicts a light tunnel structure in accordance with another embodiment of the invention, wherein previously referenced elements share the same reference numerals. In this embodiment, the first and fourth reflectors 201″ and 204 differ in length and are longer than the second and third reflectors 202 and 203. At an end of the light tunnel structure, the second and third reflectors 202, 203 have coplanar edges while the first and fourth reflectors 201″ and 204 protrude and the edges thereof are not positioned at the same plane. At the other end of the light tunnel structure, edges of the first, second, third and fourth reflectors 201″, 202, 203 and 204 are positioned at the same plane, thereby determining the positions of the reflectors 201″, 202, 203 and 204.

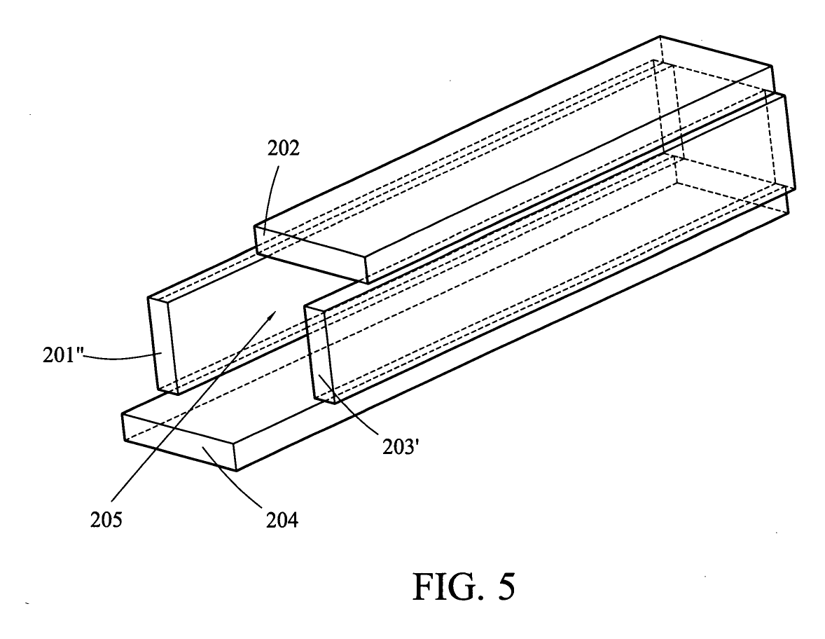

FIG. 5 depicts a light tunnel structure in accordance with another embodiment of the invention, wherein previously referenced elements share the same reference numerals. In this embodiment, the first, second, third and fourth reflectors 201″, 202, 203′ and 204 differ in length. The edges of the first, second, third and fourth reflectors 201″, 202, 203′ and 204 are not positioned at the same plane at an end of the light tunnel structure, while the edges at the other end of the light tunnel structure are positioned at the same plane thereby determining the positions of the reflectors 201″, 202, 203′ and 204.

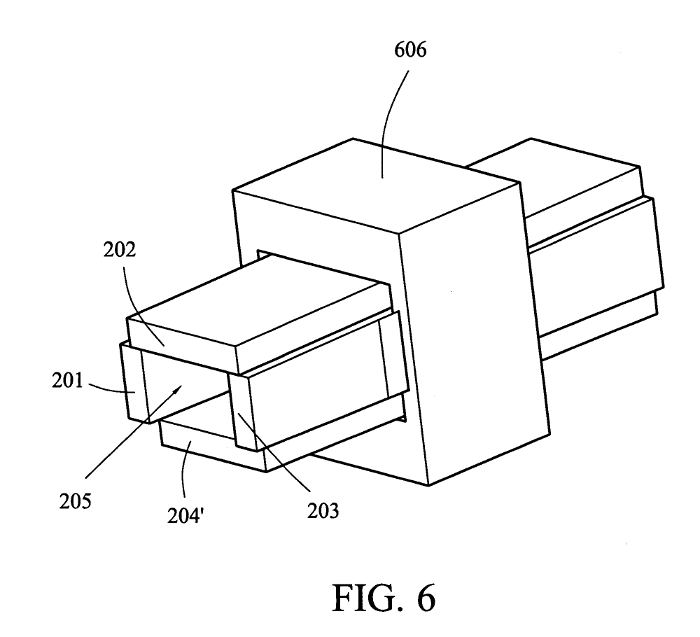

FIG. 6 depicts a light tunnel structure in accordance with another embodiment of the invention, wherein previously referenced elements share the same reference numerals. At an end of the light tunnel structure, the first, second and third reflectors 201, 202 and 203 have coplanar edges while the fourth reflector 204′ is shortened. At the other end, edges of the first, second, third and fourth reflectors 201, 202, 203 and 204′ are positioned at the same plane. In addition, a sleeve 606 fits on the outer surfaces of the first, second, third and fourth reflectors 201, 202, 203 and 204′, thereby facilitating the positioning thereof.

In the invention, one or more reflector protrudes or is shortened whereby the light beam passing through the light tunnel structure is still uniformized even when the light axis of the light source of the projection system and the central axis of the light tunnel structure 200 are not parallel.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light tunnel structure comprising:
a plurality of reflectors joined together and having edges at an end of the light tunnel structure, wherein not all of the edges at the end are positioned at a same plane.

2. The light tunnel structure as claimed in claim 1, wherein the inner surfaces of the reflectors are coated with films.

3. The light tunnel structure as claimed in claim 1, wherein the profile of the reflectors is trapezoid, rectangular or polygonal.

4. The light tunnel structure as claimed in claim 1, wherein the reflectors are made of glass.

5. The light tunnel structure as claimed in claim 1, wherein some of the reflectors have the same length.

6. The light tunnel structure as claimed in claim 1, wherein some of the reflectors have different lengths.

7. The light tunnel structure as claimed in claim 1, wherein edges of the reflectors at the other end of the light tunnel structure are positioned at a same plane.

8. The light tunnel structure as claimed in claim 1, further comprising a sleeve fit on the outer surfaces of the light tunnel structure.

9. The light tunnel structure as claimed in claim 1, wherein at least one reflector protrudes at the end of the light tunnel structure.

10. The light tunnel structure as claimed in claim 1, wherein at least one reflector is shortened at the end of the light tunnel structure.

11. A light tunnel structure comprising:
a plurality of reflectors joined together, wherein not all of the reflectors have the same length.

12. The light tunnel structure as claimed in claim 11, wherein the inner surfaces of the reflectors are coated with a film.

13. The light tunnel structure as claimed in claim 11, wherein the profile of the reflectors is trapezoid, rectangular or polygonal.

14. The light tunnel structure as claimed in claim 11, wherein the reflectors are made of glass.

15. The light tunnel structure as claimed in claim 11, wherein some of the reflectors have the same length.

16. The light tunnel structure as claimed in claim 11, wherein some of the reflectors have different lengths.

17. The light tunnel structure as claimed in claim 11, wherein edges of the reflectors at an end of the light tunnel structure are positioned at a same plane.

18. The light tunnel structure as claimed in claim 11, further comprising a sleeve fit on the outer surfaces of the light tunnel structure.

19. The light tunnel structure as claimed in claim 11, wherein at least one reflector protrudes at an end of the light tunnel structure.

20. The light tunnel structure as claimed in claim 11, wherein at least one reflector is shortened at an end of the light tunnel structure.
